(19) United States
(12) Patent Application Publication
(10) Pub. No.: US 2026/0191108 A1
(43) Pub. Date: Jul. 2, 2026

(54) WAFER SCALE SYSTEM-IN-PACKAGE STRUCTURE AND METHOD FOR FORMING THE SAME

(71) Applicant: JCET Microelectronics (Jiangyin) Co., LTD., Jiangyin (CN)

(72) Inventors: Songhua XU, Jiangyin (CN); Danfeng YANG, Jiangyin (CN); Pingping LI, Jiangyin (CN); Chao ZHANG, Jiangyin (CN); Heming ZHANG, Jiangyin (CN); Yuhao DAI, Jiangyin (CN); Yaojian LIN, Jiangyin (CN)

(73) Assignee: JCET Microelectronics (Jiangyin) Co., LTD., Jiangyin (CN)

(21) Appl. No.: 19/412,518

(22) Filed: Dec. 8, 2025

(30) Foreign Application Priority Data
Dec. 27, 2024 (CN) 202411950841.9

(51) Int. Cl. H10W 90/10; H10W 70/60; H10W 74/10

(52) U.S. Cl. CPC H10W 90/10; H10W 70/616; H10W 74/114

(57) ABSTRACT

A wafer scale system-in-package structure and a method for forming the same, the package structure includes: a redistribution layer comprising an upper surface and a lower surface opposite to the upper surface; a plurality of chip modules mounted on the upper surface of the redistribution layer and electrically connected to the redistribution layer; a back surface bridge chip mounted on the lower surface of the redistribution layer and electrically connected to the redistribution layer, where the back surface bridge chip is configured to interconnect adjacent chip modules; and a first molding layer located on the upper surface of the redistribution layer, covering the chip modules, where the first molding layer exposes the upper surface of the chip modules.

### CROSS-REFERENCE TO RELATED APPLICATIONS

This application claims the benefit of priority to Chinese Application No. 202411950841.9, filed Dec. 27, 2024, which is incorporated herein by reference in its entirety.

### TECHNICAL FIELD

The present application relates to the field of semiconductor package, and particularly relates to a wafer scale system-in-package structure and a method for forming the same.

### BACKGROUND

System in Package (SiP) is a technology that integrates chips with various different functions such as optoelectronics, digital/logic, radio frequency, memory, and etc., into a single package in the form of chip stack or package stack, thereby realizing a system that can achieve the above various functions.

The demand for data computation in today's emerging fields (mobile devices, artificial intelligence, automotive electronics, data storage, and etc.) is growing exponentially; in order to meet the requirements of high-performance computing such as high density, high speed, high heat dissipation, low power consumption, low latency and etc., existing system-in-package is expanding towards wafer scale, i.e., a plurality of chip sub-modules arranged in rows and columns are integrated on one silicon wafer to form a wafer scale system-in-package structure.

### SUMMARY

The present disclosure provides a wafer scale system-in-package structure and a method for forming the same.

A wafer scale system-in-package structure includes: a redistribution layer, the redistribution layer including opposed upper surface and lower surface; a plurality of chip modules, the plurality of chip modules being mounted on the upper surface of the redistribution layer and electrically connected with the redistribution layer; a back surface bridge chip, the back surface bridge chip being mounted on the lower surface of the redistribution layer and electrically connected with the redistribution layer, and the back surface bridge chip is used to interconnect adjacent chip modules; and a first molding layer located on the upper surface of the redistribution layer and covering the chip modules, the first molding layer exposing the upper surfaces of the chip modules.

In some implementations, the redistribution layer includes a passivation layer and a plurality of discrete first wirings and a plurality of discrete second wirings located in the passivation layer; the plurality of chip modules being electrically connected with the redistribution layer includes: the chip modules are electrically connected with a part of the first wirings and a part of the second wirings.

In some implementations, the back surface bridge chip includes a substrate and connection lines located on the substrate; the back surface bridge chip being electrically connected with the redistribution layer includes: the connection lines in the back surface bridge chip are electrically connected with a part of the second wirings, and the back surface bridge chip together with a part of the second wirings interconnect adjacent chip modules.

In some implementations, the chip module includes: a base substrate, a plurality of semiconductor chips, and a covering molding layer, wherein the base substrate includes opposed front surface and back surface, and the base substrate has in it a connection structure, the back surface of the substrate having external terminals, the external terminals being electrically connected with the connection structure and being electrically with a part of the first wirings and a part of the second wirings, the plurality of semiconductor chips being mounted on the front surface of the substrate, the semiconductor chips being electrically connected with the connection structure, and the covering molding layer being located on the front surface of the substrate and covering the plurality of semiconductor chips.

In some implementations, the type of the base substrate is a silicon base substrate, a glass base substrate, or a redistribution base substrate.

In some implementations, when the base substrate is a redistribution base substrate, a second bridge chip is further embedded in the redistribution base substrate, and the second bridge chip is electrically connected with a part of the connection structure in the redistribution base substrate.

In some implementations, the corresponding base substrates in at least two adjacent chip modules in the system-in-package structure are of the same type or different types.

In some implementations, the corresponding base substrates in at least two adjacent chip modules in the system-in-package structure being of the same type includes: the corresponding base substrates in at least two adjacent chip modules in the system-in-package structure are both silicon base substrates; or the corresponding base substrates in at least two adjacent chip modules in the system-in-package structure are both glass base substrates; or the corresponding base substrates in at least two adjacent chip modules in the system-in-package structure are both redistribution base substrates.

In some implementations, the corresponding base substrates in at least two adjacent chip modules in the system-in-package structure being of different types includes: the types of the corresponding base substrates in at least two adjacent chip modules in the system-in-package structure are: one type is a silicon base substrate and another type is a glass base substrate; or the types of the corresponding base substrates in at least two adjacent chip modules in the system-in-package structure are: one type is a silicon base substrate and another type is a redistribution base substrate; or the types of the corresponding base substrates in at least two adjacent chip modules in the system-in-package structure are: one type is a glass base substrate and another type is a redistribution base substrate.

In some implementations, the connection structure is one or more of a metal layer, a connection plug, a through-via connection structure, and a via connection structure.

In some implementations, it further includes: a plurality of discrete metal bumps located on the lower surface of the redistribution layer, the metal bumps being electrically connected with the corresponding first wirings; a second molding layer located on the lower surface of the redistribution layer and covering the metal bumps and the back surface bridge chip, the second molding layer exposing the lower surface of the metal bumps.

In some implementations, it further includes: a first bridge structure mounted on the upper surface of the redistribution layer at the edge of the chip module, and the first bridge structure is used to interconnect adjacent chip modules.

In some implementations, it further includes: a second bridge structure mounted on the upper surface of the redistribution layer at the corner head of the chip module, and the second bridge structure is used to interconnect adjacent chip modules around the corner head; and edge dummy devices of different sizes mounted on the upper surface and/or lower surface of the edge areas of the redistribution layer outside the chip module array.

In some implementations, the redistribution layer further includes a plurality of discrete third wirings located in the passivation layer, and the chip modules are also electrically connected with a part of the third wirings; the first bridge structure includes a first line layer and a first support layer located on the upper surface of the first line layer, and the first line layer includes a first dielectric layer, first lines located in the first dielectric layer, and a first welding bump protruding from the lower surface of the first dielectric layer and electrically connected with the first lines; when the first bridge structure is mounted on the redistribution layer, the first welding bump is electrically connected with the corresponding third wirings in the redistribution layer, and the first bridge structure together with the third wirings in the redistribution layer interconnects adjacent chip modules.

In some implementations, the redistribution layer further includes a plurality of discrete fourth wirings in the passivation layer, and the chip modules are also electrically connected with a part of the fourth wirings; the second bridge structure includes a second line layer and a second support layer on the upper surface of the second line layer, and the second line layer includes a second dielectric layer, second lines located in the second dielectric layer, and a second welding bump protruding from the lower surface of the second dielectric layer and electrically connected with the second lines; when the second bridge structure is mounted on the redistribution layer, the second welding bump is electrically connected with the corresponding fourth wirings in the redistribution layer, and the second bridge structure together with the fourth wirings in the redistribution layer interconnects adjacent chip modules around the corner head.

In some implementations, the edge dummy components include one or more of a passive device, a heat dissipation discrete component, or a dummy chip.

In another aspect, the present application further provides a method for forming a wafer scale system-in-package structure, which includes: forming a redistribution layer, the redistribution layer including opposed upper surface and lower surface; providing a plurality of chip modules, mounting the plurality of chip modules on the upper surface of the redistribution layer and electrically connecting it with the redistribution layer; providing a back surface bridge chip, mounting the back surface bridge chip on the lower surface of the redistribution layer and electrically connecting it with the redistribution layer, and the back surface bridge chip is used to interconnect adjacent chip modules; and covering the chip modules with a first molding layer on the upper surface of the redistribution layer, the first molding layer exposing the upper surfaces of the chip modules.

In some implementations, the process of forming the redistribution layer includes: providing a carrier board; forming a redistribution layer on the carrier board, the redistribution layer includes a passivation layer and a plurality of discrete first wirings and a plurality of discrete second wirings located in the passivation layer; after forming the first molding layer, removing the carrier board and mounting the back surface bridge chip; the plurality of chip modules being electrically connected with the redistribution layer includes: the chip modules are electrically connected with a part of the first wirings and a part of the second wirings.

In some implementations, the back surface bridge chip includes a substrate and connection lines on the substrate; the back surface bridge chip being electrically connected with the redistribution layer includes: the connection lines in the back surface bridge chip are electrically connected with a part of the second wirings, and the back surface bridge chip together with a part of the second wirings interconnects adjacent chip modules.

In some implementations, the chip module includes: a base substrate, a plurality of semiconductor chips, and a covering molding layer, wherein the base substrate includes opposed front surface and back surface, and the base substrate has in it a connection structure, the back surface of the substrate having external terminals, the external terminals being electrically connected with the connection structure and being electrically with a part of the first wirings and a part of the second wirings, the plurality of semiconductor chips being mounted on the front surface of the substrate, the semiconductor chips being electrically connected with the connection structure, and the covering molding layer being located on the front surface of the substrate and covering the plurality of semiconductor chips.

In some implementations, the type of the base substrate is a silicon base substrate, a glass base substrate, or a redistribution base substrate.

In some implementations, when the base substrate is a redistribution base substrate, a second bridge chip is further embedded in the redistribution base substrate, and the second bridge chip is electrically connected with a part of the connection structure in the redistribution base substrate.

In some implementations, the corresponding base substrates in at least two adjacent chip modules in the system-in-package structure are of the same type or different types.

In some implementations, it further includes: mounting a first bridge structure on the upper surface of the redistribution layer at the edge of the chip module, and the first bridge structure is used to interconnect adjacent chip modules.

In some implementations, it further includes: mounting a second bridge structure on the upper surface of the redistribution layer at the corner head of the chip module, and the second bridge structure is used to interconnect adjacent chip modules around the corner head; mounting edge dummy devices of different sizes on the upper surface and/or lower surface of the edge areas of the redistribution layer outside the chip module array.

### BRIEF DESCRIPTION OF THE DRAWINGS

FIGS. 1-2 are top-view structural schematic diagrams of a wafer scale system-in-package structure in one embodiment of the present application, wherein FIG. 2 is a cross-sectional structural schematic diagram along the direction of the cutting line CC1 in FIG. 1;

FIG. 3 is a structural schematic diagram of a wafer scale system-in-package structure in another embodiment of the present application;

FIG. 4 is a structural schematic diagram of the wafer scale system-in-package structure in yet another embodiment of the present application;

FIG. 5 is a structural schematic diagram of the wafer scale system-in-package structure in yet another embodiment of the present application;

FIG. 6 is a structural schematic diagram of the wafer scale system-in-package structure in yet another embodiment of the present application;

FIG. 7 is a structural schematic diagram of a wafer scale system-in-package structure in yet another embodiment of the present application; and

FIGS. 8-10 are structural schematic diagrams of a wafer scale system-in-package structure in yet another embodiment of the present application, wherein FIG. 9 is a cross-sectional structural schematic diagram along the direction of the cutting line AA1 in FIG. 8, and FIG. 10 is a cross-sectional structural schematic diagram along the direction of the cutting line BB1 in FIG. 8.

### DETAILED DESCRIPTION

The specific implementations of the present application are described in detail below in conjunction with the accompanying drawings. For the sake of explanation, when describing the embodiments of the present application in detail, the schematic diagram will not be enlarged to a general proportion; furthermore, the schematic diagram is merely an example, which should not limit the scope of protection of the present application. Additionally, in actual production, the three-dimensional spatial dimensions of length, width, and depth should be included.

The band-width of existing wafer scale system-in-package structures still needs to be improved.

In the wafer scale system-in-package structure and the method for forming the same in the aforementioned embodiments of the present application, the package structure includes: a redistribution layer, the redistribution layer including opposed upper surface and lower surface; a plurality of chip modules, the plurality of chip modules mounted on the upper surface of the redistribution layer and electrically connected with the redistribution layer; a back surface bridge chip, the back surface bridge chip mounted on the lower surface of the redistribution layer and electrically connected with the redistribution layer, and the back surface bridge chip is used to interconnect adjacent chip modules; and a first molding layer located on the upper surface of the redistribution layer and covering the chip modules, the first molding layer exposing the upper surfaces of the chip modules. Therefore, in the present application, in addition to the fact that the adjacent chip modules may be interconnected through the wiring layer (the first wirings in it), the adjacent chip modules may further be interconnected through the back surface bridge chip.

Furthermore, the type of the base substrate includes a silicon base substrate, a glass base substrate, or a redistribution base substrate, the corresponding base substrates in at least two adjacent chip modules in the system-in-package structure are of the same type or different types.

Furthermore, the wafer scale system-in-package structure further includes: a first bridge structure mounted on the upper surface of the redistribution layer at the edge of the chip module, and the first bridge structure is used to interconnect adjacent chip modules; a second bridge structure mounted on the upper surface of the redistribution layer at the corner head of the chip module, and the second bridge structure is used to interconnect adjacent chip modules around the corner head.

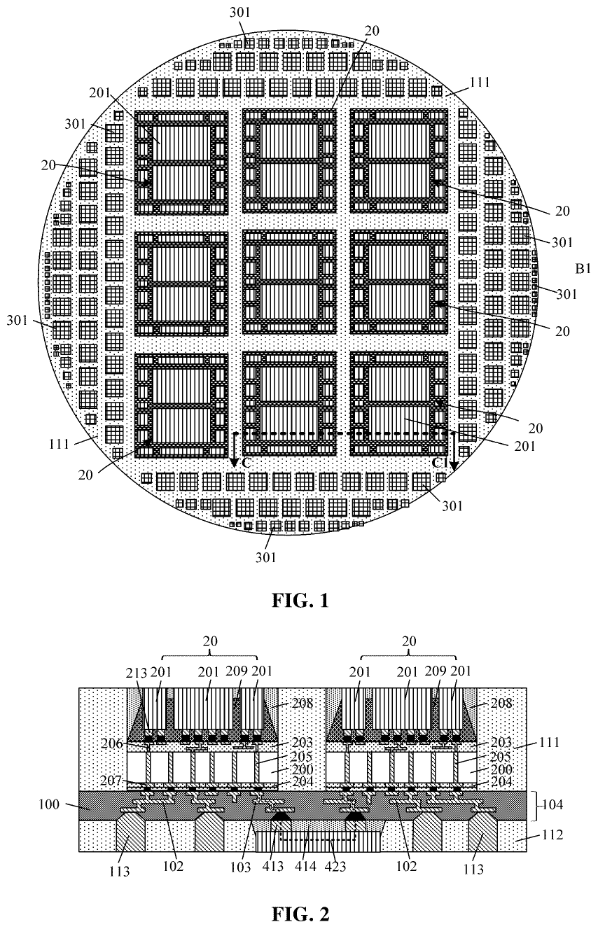

An embodiment of the present application first provides a wafer scale system-in-package structure in conjunction with FIGS. 1-2, wherein FIG. 2 is a cross-sectional structural schematic diagram along the direction of the cutting line CC1 in FIG. 1, and it includes: a redistribution layer 104, the redistribution layer including opposed upper surface and lower surface; a plurality of chip modules 20, the plurality of chip modules 20 being mounted on the upper surface of the redistribution layer 104 and electrically connected with the redistribution layer 104; a back surface bridge chip 423 (referring to FIG. 2), the back surface bridge chip 423 being mounted on the lower surface of the redistribution layer 104 and electrically connected with the redistribution layer 104, and the back surface bridge chip 423 is used to interconnect adjacent chip modules 20; and a first molding layer 111 located on the upper surface of the redistribution layer 104 and covering the chip modules 20, the first molding layer 111 exposing the upper surfaces of the chip modules 20.

In one embodiment, the redistribution layer 104 includes a passivation layer 100 and a plurality of discrete first wirings 102 and a plurality of discrete second wirings 103 located in the passivation layer 100. A part of the first wirings 102 may be used for electrical connections between the upper surface and lower surface of the redistribution layer 104, and a part of the first wirings 102 is used for electrical connections between adjacent chip modules 20, and the second wirings 103 are used for electrical connections with the chip module 20 and the back surface bridge chip 423, and the passivation layer 100 is used for electrical isolation between the first wirings 102, between the second wirings 103, and between the first wirings 102 and the second wirings 103. In one embodiment, the passivation layer 100 may be a single layer or a multi-layer stacked structure, and correspondingly, the first wirings 102 and the second wirings 103 may also be single-layer or multi-layer line structures. The passivation layer 100 may be one or more of silicon oxide, silicon nitride, silicon oxynitride, silicon oxycarbide, or silicon carbonitride; the first wirings 102 and the second wirings 103 may be one or more of Al, Cu, W, Au, Ag, Pt, Ni, Ti, Ta, TiN, TaN, TaC, or WN.

The package structure is a wafer scale system-in-package structure, and the size of the wafer scale system-in-package structure is large, the corresponding size of the redistribution layer 104 is also large. In some implementations, when the redistribution layer 104 is circular, the diameter size of the redistribution layer 104 may be 300 mm or 450±5 mm; when the redistribution layer 104 is square, the diagonal size of the redistribution layer 104 may be 300 mm or 450±10 mm.

The back surface bridge chip 423 is used to interconnect adjacent chip modules 20. In one embodiment, the back surface bridge chip 423 includes a substrate and connection lines located on the substrate, and the density of the connection lines in the back surface bridge chip 423 is greater than the density of the wirings (e.g., the first wirings 102 and the second wirings 103) in the redistribution layer 104, and higher wiring density can be achieved within a given space through the back surface bridging chip 423. The substrate is a semiconductor substrate, and may be a silicon substrate, germanium substrate, or silicon nitride substrate; the connection lines are single-layer or multi-layer connection lines, and the material of the connection lines is metal, and the connection lines are isolated from each other by a dielectric layer located on the surface of the substrate; the dielectric layer may be a single-layer or multi-layer structure, and the material of the dielectric layer may be one or more of silicon oxide, silicon nitride, silicon oxynitride, silicon oxycarbide, or silicon carbonitride; the electrical connection of the back surface bridge chip 423 with the redistribution layer 104 includes: the connection lines in the back surface bridge chip 423 being electrically connected with a part of the second wirings 103, i.e., the back surface bridge chip 423, together with a part of the second wirings 103, interconnects adjacent chip modules 20. Therefore, in the present application, in addition to the fact that the adjacent chip modules 20 are interconnected through the first wirings 102 in the redistribution layer 104, the adjacent chip modules 20 may further be interconnected through the back surface bridge chip 423 and the second wirings 103 in the redistribution layer 104 (communication and/or data transfer between adjacent chip modules 20 is enabled when interconnected), thereby achieving diversity in interconnection between the adjacent chip modules 20, which further improves the band-width between adjacent chip modules 20, thus improving the overall band-width of the wafer scale system-in-package structure.

In some implementations, the back surface bridge chip 423 includes opposed first surface and second surface, and the first surface has protruding welding bumps 413; when the back surface bridge chip 423 is mounted on the lower surface of the redistribution layer 104, the first surface face of the back surface bridge chip 423 faces the lower surface of the redistribution layer 104, and the welding bumps 413 of the first surface of the back surface bridge chip 423 are welded together with the second wirings 103 in the redistribution layer 104 through solder. In one embodiment, an underfill layer 414 is further filled between the first surface of the back surface bridge chip 423 and the lower surface of the redistribution layer 104.

In one embodiment, the system-in-package structure further includes: a plurality of discrete metal bumps 113 located on the lower surface of the redistribution layer 104, the metal bumps 113 are electrically connected with corresponding first wirings 102; and a second molding layer 112 located on the lower surface of the redistribution layer 104 and covering the metal bumps 113 and the back surface bridge chip 423, and the second molding layer 112 exposes the lower surface of the metal bumps 113, the metal bumps 113 serve as ports for connecting the system-in-package structure with other package structures, devices, or substrates. In one embodiment, the material of the metal bump 113 is one or more of Al, Cu, W, Au, Ag, Pt, Ni, Ti, Ta, TiN, TaN, TaC, or WN. The materials of the first molding layer 111 and the second molding layer 112 may be filler-containing or filler-free epoxy resin, polyimide resin, benzocyclobutene resin, or polybenzoxazole resin; in some implementations, they may also be filler-containing or filler-free polybutylene terephthalate, polycarbonate, polyethylene terephthalate, polyethylene, polypropylene, polyolefin, polyurethane, polyolefin, polyether sulfone, polyamide, polyurethane, ethylene-vinyl acetate copolymer, or polyvinyl alcohol. In some embodiments, the filler may be an inorganic filler or an organic filler.

The chip module 20 has specific functions. A plurality of chip modules 20 are mounted in an array arrangement on the upper surface of the redistribution layer 104. The number of chip modules 20 is at least two, in some implementations, it may be two, four, nine, sixteen, twenty-five, or more (e.g., N², where N is greater than five), a plurality of chip modules 20 may be mounted in a 1×1, 2×2, 3×3, 4×4, 5×5 array arrangement, or in an array arrangement with more modules, on the upper surface of the redistribution layer 104. FIG. 1 illustrates an example where nine chip modules 20 are mounted in a 3×3 array arrangement on the upper surface of the redistribution layer 104. In one embodiment, the system-in-package structure further includes: edge dummy devices 301 of different sizes mounted on the upper surface and/or lower surface of the edge area of the redistribution layer 104 outside the chip module array; in some implementations, the edge dummy devices 301 may be mounted merely on the upper surface or lower surface of the edge area of the redistribution layer 104 outside the chip module array, or the edge dummy devices 301 are mounted on both the upper surface and lower surface of the edge area of the redistribution layer 104 outside the chip module array, and the edge dummy devices 301 will be described in detail again in subsequent embodiments.

In one embodiment, each chip module 20 includes in it a plurality of semiconductor chips 201, in some implementations, each chip module 20 includes one or at least two (two or more than two) semiconductor chips 201. In some implementations, when each chip module 20 includes at least two semiconductor chips 201, the dimension and/or function of the at least two semiconductor chips 201 are different. In some implementations, when each chip module 20 includes at least two semiconductor chips 201, the dimension and/or function of a partial number of the semiconductor chips 201 may be the same, and the dimension and/or function of a partial number of the semiconductor chips 201 may be different. In one embodiment, the semiconductor chip 201 includes but is not limited to a logic chip, a memory chip, and a sensor chip. In some implementations, the logic chip may include but is not limited to Gate Array (GA), Unit Base Substrate Array (UBSA), Embedded Array (EA), Structured Application Specific Integrated Circuit (ASIC), Field Programmable Gate Array (FPGA), Complex Programmable Logic Device (CPLD), Graphics Processing Unit (GPU), Central Processing Unit (CPU), Microprocessor Unit (MPU), Microcontroller Unit (MCU), Logic Integrated Circuit (IC), Application Processor (AP), Display Driver IC (DDI), Radio Frequency (RF) Chip, Power Chip, or Complementary Metal Oxide Semiconductor (CMOS) Image Sensor. The storage chip may include but is not limited to Dynamic Random Access Memory (DRAM), Static Random-Access Memory (SRAM), Magnetoresistive Random Access Memory (MRAM), Phase-change Memory (PCM), Resistive Random Access Memory (RRAM), or Non-Volatile Memory (NVM) such as Flash Memory.

In one embodiment, the chip module 20 includes: a base substrate 200, a plurality of semiconductor chips 201, and a covering molding layer 208, wherein the base substrate 200 includes opposed front surface and back surface, and the base substrate 200 has in it a connection structure 205, and the back surface of the base substrate 200 has an external terminal 207, the external terminal 207 is electrically connected with the connection structure 205, the plurality of semiconductor chips 201 are mounted on the front surface of the base substrate 200, and the semiconductor chips 201 are electrically connected with the connection structure 205, and the covering molding layer 208 is located on the front surface of the base substrate 200 and covers the plurality of the semiconductor chips 201. The electrical connection of the chip module with the redistribution layer includes: the external terminals 207 on the chip module are electrically connected with a part of the first wirings 102 and a part of the second wirings 103 in the redistribution layer 104.

In one embodiment, the chip modules 20 being mounted on the upper surface of the redistribution layer 104 includes: each chip module 20 is mounted on the upper surface of the redistribution layer 104 in a flip-chip manner, in some implementations, the external terminals 207 in the chip modules 20 are welded together with corresponding first wirings 102 and second wirings 103 in the redistribution layer 104 through solder.

In one embodiment, the semiconductor chip 201 includes opposed active surface and back surface, and the active surface has on it welding bumps 213, and the semiconductor chip 201 forms in it an integrated circuit with specific functions (not shown in the figures), and the welding bumps 213 are electrically connected with the integrated circuit. A plurality of the semiconductor chips 201 being mounted on the front surface of the base substrate 200 includes: a plurality of the semiconductor chips 201 are mounted on the front surface of the base substrate 200 in a flip-chip manner, in some implementations, the active surfaces of the semiconductor chips 201 face downward, and the welding bumps 213 on the active surfaces of the semiconductor chips 201 are welded together with the base substrate 200. In one embodiment, the welding bump 213 may include a pad and a solder layer located on the surface of the pad; in another embodiment, the welding bump 213 may also include a pad, a metal pillar located on the surface of the pad, and a solder layer on the top surface of the metal pillar. The material of the pad and metal pillar is metal, which may be one or more of aluminum, copper, nickel, tin, titanium, tungsten, platinum, chromium, tantalum, gold, or silver. The material of the solder layer is tin or tin alloy, the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

In one embodiment, an underfill layer 209 is further filled between the active surface of the semiconductor chip 201 and the front surface of the base substrate 200, and the covering molding layer 208 further covers the underfill layer. The materials of the underfill layer 209 and the covering molding layer 208 may be both resin.

In one embodiment, the front surface of the base substrate 200 further has a redistribution layer, and the redistribution layer includes a first dielectric layer 203 located on the front surface of the base substrate 200 and metal lines 206 located in the first dielectric layer 203, and the upper surface of the first dielectric layer 203 exposes a part of the metal lines 206. When the welding bumps 213 on the active surface of the semiconductor chip 201 are welded together with the base substrate 200, the welding bumps 213 on the active surface of the semiconductor chip 201 are welded together with corresponding metal lines 206 in the redistribution layer on the base substrate 200, i.e., the semiconductor chip 201 is electrically connected with the connection structure 205 through the metal lines 206. The back surface of the base substrate 200 further has a second dielectric layer 204, and the second dielectric layer 204 exposes the lower surface of the external terminal 207. In one embodiment, the materials of the first dielectric layer 203 and the second dielectric layer 204 may be inorganic material or organic material, the inorganic material may be one or more of silicon oxide, silicon nitride, silicon oxynitride, silicon oxycarbide, or silicon carbonitride, the organic materials may be polymeric resin material, in some implementations, it may include epoxy resin, polyimide resin, benzocyclobutene resin, or polybenzoxazole resin. The materials of the metal lines 206 and external terminal 207 are metals, in some implementations, they may be one or more of Al, Cu, W, Au, Ag, Pt, Ni, Ti, Ta, TiN, TaN, TaC, or WN.

The corresponding base substrates 200 in at least two adjacent chip modules 20 in the system-in-package structure are of the same type or different types to meet different performance requirements, different functional requirements and different package requirements of the package structure. In one embodiment, the type of the base substrate 200 includes a silicon base substrate, a glass base substrate, or a redistribution base substrate, and the redistribution base substrates include two types: a redistribution base substrate embedded with bridge chips and a redistribution base substrate not embedded with bridge chips, in some implementations, a second bridge chip 210 (referring to FIG. 4) is embedded in the redistribution base substrate embedded with bridge chips, the second bridge chip 210 is electrically connected with a part of the connection structures 205 in the redistribution base substrate. The connection structures 205 are one or more of a metal layer, a connection plug, a through-via connection structure, or a via connection structure. In some implementations, referring again to FIG. 2, the corresponding base substrates 200 in at least two adjacent chip modules 20 in the system-in-package structure are of the same type, and the base substrates 200 are all silicon base substrates, the connection structures 205 are through-via connection structures, and may be Through-Silicon-Via connection structures (TSVs).

In some implementations, referring again to FIG. 2, the corresponding base substrates 200 in at least two adjacent chip modules 20 in the system-in-package structure are of the same type, and the base substrates 200 are all glass base substrates, and the connection structure 205s are via connection structures.

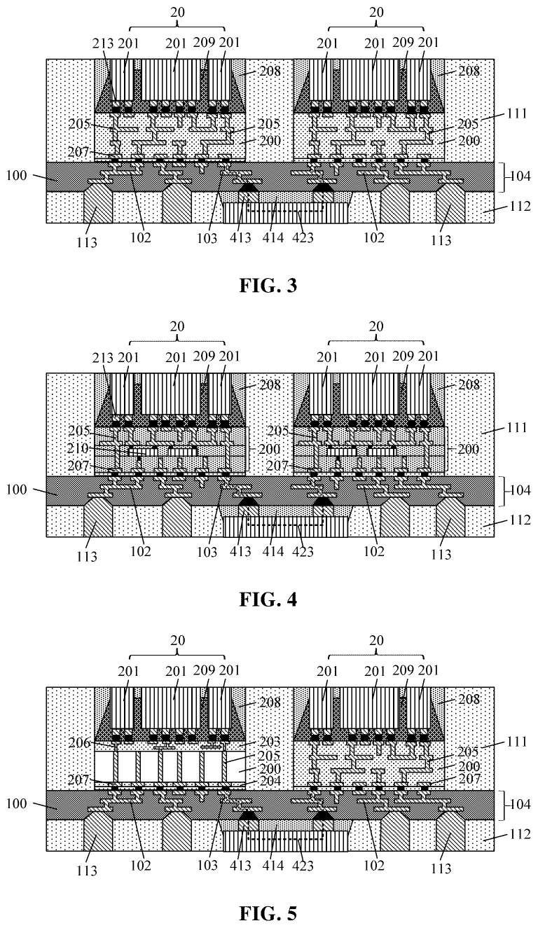

In some implementations, referring to FIG. 3, the corresponding base substrates 200 in at least two adjacent chip modules 20 in the system-in-package structure are of the same type, and the base substrates 200 are all redistribution base substrates (without embedded bridge chips), the connection structures 205 in the base substrates 200 are metal layers and connection plugs. The material of the base substrate 200 is resin or other suitable material.

In some implementations, referring to FIG. 4, the corresponding base substrates 200 in at least two adjacent chip modules 20 in the system-in-package structure are of the same type, and the base substrates 200 are all redistribution base substrates, the connection structures 205 in the base substrates 200 are metal layers and connection plugs, and a second bridge chip 210 is embedded in the redistribution base substrate, and the second bridge chip 210 is electrically connected with a part of the connection structures 205 in the redistribution base substrate. The number of second bridge chips 210 may be one or more. The second bridge chip 210 has in it connection lines with a higher density than in the redistribution base substrate, thereby achieving higher wiring density within a given space.

In some implementations, the corresponding base substrates 200 in at least two adjacent chip modules 20 in the system-in-package structure are of different types, in some implementations, the types of the corresponding base substrates 200 in at least two adjacent chip modules 20 in the system-in-package structure are: one type is a silicon base substrate and another type is a glass base substrate.

In some implementations, referring to FIG. 5, the corresponding base substrates 200 in at least two adjacent chip modules 20 in the system-in-package structure are of different types, in some implementations, the types of the corresponding base substrates 200 in at least two adjacent chip modules 20 in the system-in-package structure are: one type is a silicon base substrate and another type is a redistribution base substrate (without embedded bridge chips).

In some implementations, referring again to FIG. 5, the corresponding base substrates 200 in at least two adjacent chip modules 20 in the system-in-package structure are of different types, in some implementations, the type of the corresponding base substrates 200 in at least two adjacent chip modules 20 in the system-in-package structure are: one type is a glass base substrate and another type is a redistribution base substrate (without embedded bridge chips).

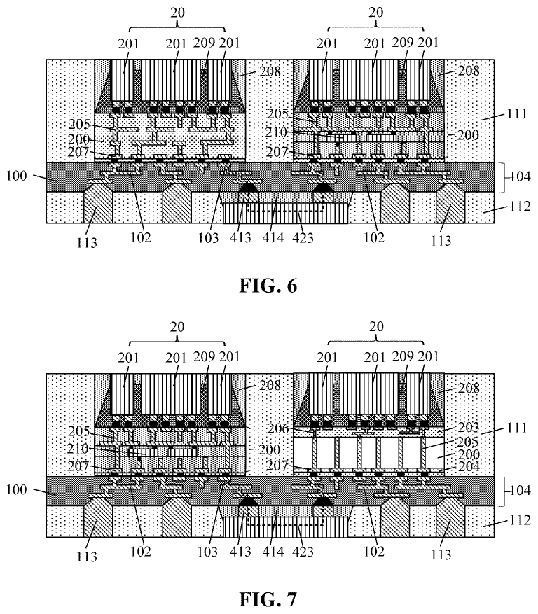

In some implementations, referring again to FIG. 6, the corresponding base substrates 200 in at least two adjacent chip modules 20 in the system-in-package structure are of different types, in some implementations, the types of the corresponding base substrates 200 in at least two adjacent chip modules 20 in the system-in-package structure are: one type is a redistribution base substrate (without embedded bridge chips) and another type is a redistribution base substrate embedded with a second bridge chip 210.

In some implementations, referring again to FIG. 7, the corresponding base substrates 200 in at least two adjacent chip modules 20 in the system-in-package structure are of different types, in some implementations, the types of the corresponding base substrates 200 in at least two adjacent chip modules 20 in the system-in-package structure are: one type is a silicon substrate or a glass substrate and another type is a redistribution base substrate embedded with a second bridge chip 210.

In one embodiment, each chip module 20 may be rectangular or cubic, and each chip module 20 includes four corner heads and edges between adjacent corner heads, i.e., it includes four corner heads and four edges. In other embodiments, the chip module 20 may be other shapes, such as cuboid-like, cube-like, parallelepiped, or other regular three-dimensional shapes.

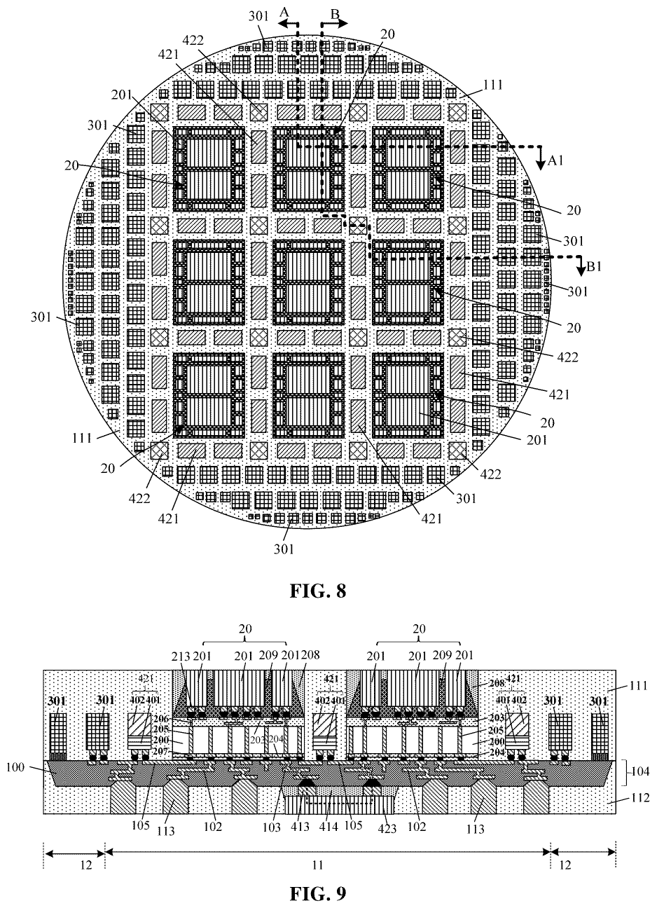

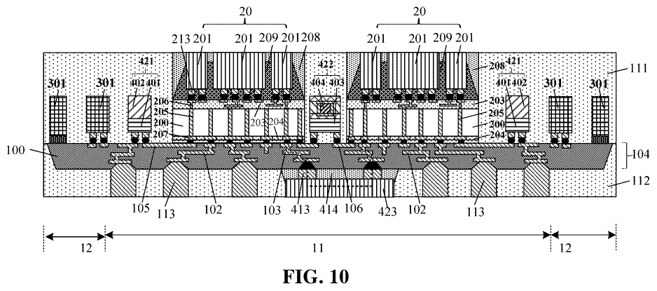

In another embodiment, referring to FIGS. 8-10, FIG. 9 is a cross-sectional structural schematic diagram along the direction of the cutting line AA1 in FIG. 8, FIG. 10 is a sectional structural schematic diagram along the direction of the cutting line BB1 in FIG. 8, the main difference between the present embodiment and the aforementioned embodiments lies in: the wafer scale system-in-package structure further includes: a first bridge structure 421 mounted on the upper surface of the redistribution layer 104 at the edges of the chip module 20 (referring to FIGS. 8 and 9), and the first bridge structure 421 is used to interconnect adjacent chip modules 20; and a second bridge structure 422 mounted on the upper surface of the redistribution layer 104 at the corner head of the chip module 20 (referring to FIGS. 8 and 10), and the second bridge structure 422 is used to interconnect adjacent chip modules 20 around the corner head. Through the first bridge structure 421 and the second bridge structure 422, the connection channels between adjacent chip modules 20 are further increased (in addition to the first wirings in the redistribution layer 104 and the back surface bridge chip 423, it also includes the first bridge structure 421 and the second bridge structure 422), thereby further improving the band-width between adjacent chip modules 20, and thus further improving the overall band-width of the wafer scale system-in-package structure.

In some implementations, the first bridge structure 421 interconnects two adjacent chip modules 20 on two sides. In some implementations, the second bridge structure 422 may interconnect adjacent two, three, or four chip modules 20 around it.

In one embodiment, referring again to FIGS. 8 and 9, the redistribution layer 104 further includes a plurality of discrete third wirings 105 located in the passivation layer 100, and the chip module 20 is further electrically connected with a part of the third wirings 105; the first bridge structure 421 includes a first line layer 401 and a first support layer 402 located on the upper surface of the first line layer 401, and the first line layer 401 includes a first dielectric layer, first lines (not shown in the FIGS) in the first dielectric layer, and a first welding bump protruding from the lower surface of the first dielectric layer and electrically connected with the first lines; when the first bridge structure 421 is mounted on the redistribution layer 104, the first welding bump is electrically connected with the corresponding third wirings 105 in the redistribution layer 104, and the first bridge structure 421, together with the third wirings 105 in the redistribution layer 104, interconnects adjacent chip modules 20. The first bridge structure 421 uses the aforementioned specific structure to interconnect adjacent chip modules 20 through the first line layer 401, such that the connection channels between adjacent chip modules 20 are increased, thereby improving the band-width between adjacent chip modules 20, and thus improving the overall band-width of the wafer scale system-in-package structure. Meanwhile, the first support layer 402 provides physical support for the first line layer 401 (because the thickness of the first line layer 401 is typically very thin and cannot be processed as a standalone device) and protects the first line layer 401 from failures such as breakage of lines caused by warping; moreover, the first support layer 402 can also reduce the amount of the first molding layer 111 formed on the upper surface of the redistribution layer 104, thereby increasing the Si/EMC ratio within the wafer scale system-in-package structure (the first support layer 402 is equivalent to Si), thus reducing the overall warping caused by the low Si/EMC ratio in the wafer scale system-in-package structure. In other embodiments, the first bridge structure 421 may include merely the first line layer 401.

The first dielectric layer in the first line layer 401 is used for isolation between the first lines. In one embodiment, the first dielectric layer may be a single layer or a multi-layer stacked structure, and the material of the first dielectric layer is one or more of silicon oxide, silicon nitride, silicon oxynitride, silicon oxycarbide, or silicon carbonitride. The first lines may also be a single-layer or a multi-layer line structure, and the material of the first lines is a metal, in some implementations, it may be one or more of Al, Cu, W, Au, Ag, Pt, Ni, Ti, Ta, TiN, TaN, TaC, or WN.

In one embodiment, the number of the first bridge structures 421 mounted on the upper surface of the redistribution layer 104 at each edge of the chip module 20 is one or more, and when the number of first bridge structures 421 is multiple, such as two or three, the plurality of first bridge structures 421 are arranged in a direction parallel to the edge of the chip module 20.

In one embodiment, the first support layer 402 is a single layer or a multi-layer stacked structure. The material of the first support layer 402 is one or more of silicon, germanium-silicon, silicon carbide, glass, resin, or PCB core.

In one embodiment, referring again to FIGS. 8 and 10, the redistribution layer 104 further includes a plurality of discrete fourth wirings 106 located in the passivation layer 100, and the chip module is further electrically connected with the fourth wirings; the second bridge structure 422 includes a second line layer 403 and a second support layer 404 located on the upper surface of the second line layer 403, and the second line layer 403 includes a second dielectric layer, second lines located in the second dielectric layer, and a second welding bump protruding from the lower surface of the second dielectric layer and electrically connected with the second lines, and when the second bridge structure 422 is mounted on the silicon substrate, the second welding bump is electrically connected with the corresponding fourth wirings 106 in the redistribution layer 104, and the second bridge structure 422, together with the corresponding fourth wirings 106 in the redistribution layer 104, interconnects adjacent chip modules 20 around the corner head. Through the second bridge structure 422 of the aforementioned specific structure, the channels connecting adjacent chip modules 20 are further increased through the second bridge structure 422, thereby further improving the band-width between adjacent chip modules 20, and thus further improving the overall band-width of the wafer scale system-in-package structure. Meanwhile, the second support layer 404 provides physical support for the second line layer 403 (because the thickness of the second line layer 403 is typically very thin and cannot be processed as a standalone device) and protects the second line layer 403 from failures such as breakage of lines caused by warping; moreover, the large stresses present at the corner heads and near the corner heads of adjacent chip modules 20 can be further buffered and balanced through the second support layer 404, so that the warping in the wafer scale system-in-package structure caused by large stress at the corner heads of the chip modules 20 is reduced.

The second dielectric layer in the second line layer 403 is used for the isolation between the second lines, the second dielectric layer may be a single layer or a multi-layer stacked structure, and the material of the second dielectric layer is one or more of silicon oxide, silicon nitride, silicon oxynitride, silicon oxycarbide, or silicon carbonitride. The second lines may also be a single-layer or a multi-layer circuit structure, and the material of the second lines is metal, in some implementations, may be one or more of Al, Cu, W, Au, Ag, Pt, Ni, Ti, Ta, TiN, TaN, TaC, or WN.

In one embodiment, the number of the second bridge structure 422 mounted on the upper surface of the redistribution layer 104 at each corner head of the chip module 20 is one, and the second bridge structure 422 is used to interconnect two or four adjacent chip modules 20 around the corner head.

In one embodiment, the second support layer 404 is a flexible structure, and the rigidity of the second support layer 404 is less than the rigidity of the first molding layer 111, so that the second support layer 404 can effectively buffer and balance the large stresses at the corner heads and near the corner heads of adjacent chip modules 20, thereby effectively reducing the warping in wafer scale system-in-package structures caused by large stresses present at the corner heads of chip modules 20.

In one embodiment, the second support layer 404 of the flexible structure includes a first buffer layer, a core layer located on the surface of the first buffer layer, and a second buffer layer located on the surface of the core layer, the core layer has in it blind vias. There are cavities in the blind vias, or the blind vias are filled with filler material. The rigidity of the second support layer of this structure is small, so that the larger stresses present at the corner heads and near the corner heads of adjacent chip modules are effectively buffered and balanced.

In one embodiment, the system-in-package structure further includes: edge dummy devices 301 of different sizes mounted on the upper surface of the edge area 12 of the redistribution layer 104 outside the array of the chip modules 20. A plurality of edge dummy devices 301 of different sizes are mounted on the upper surface of the edge area 12 of the redistribution layer 104, such that the amount of the first molding layer 111 on the upper surface of the edge area 12 of the redistribution layer 104 is reduced, thereby improving the Si/EMC ratio of the edge area 12 (the EMC is molding material, and the edge dummy devices 301 are equivalent to Si), and thus reducing the difference between the Si/EMC ratio of the edge area 12 and the Si/EMC ratio of the central area 11, therefore, the warping problems in wafer scale system-in-package structures caused by caused by the large difference in Si/EMC ratio between the edge area 12 and central area 11, thereby effectively controlling warping of system-in-package structures of wafer scale ultra large chip module at room temperature or high temperature.

In one embodiment, the edge dummy devices 301 may be one or more of a passive device, a heat dissipation discrete component, or a dummy chip. In some implementations, when the edge dummy devices 301 mounted on the upper surface of the edge area of the redistribution layer 104 are passive devices, the passive devices may be electrically connected with the redistribution layer 104, and the passive devices may be one or more of a resistor, a capacitor, or an inductor. In some implementations, when the edge dummy devices 301 mounted on the upper surface of the edge area of the redistribution layer 104 are heat dissipation discrete components, such as heat dissipation metal blocks, and the lower surface of the heat dissipation discrete components is adhered on the upper surface of the edge area 12 of the redistribution layer 104 through a heat dissipation adhesive, and the heat dissipation discrete components may be used for heat dissipation of the package structure, and the material of the heat dissipation discrete components is a metal material for heat dissipation. In some implementations, when the edge dummy devices 301 mounted on the upper surface of the edge area of the redistribution layer 104 are dummy chips, the lower surface of the dummy chips is adhered on the upper surface of the edge area 12 of the redistribution layer 104 through an adhesive, and the dummy chips are silicon dies without lines.

In one embodiment, the dimensions of edge dummy devices 301 far away from the central area 11 are smaller than the dimensions of edge dummy devices 301 closer to the central area 11. By fully mounting edge dummy devices 301 on the upper surface of the edge area 12, the material of the first molding layer 111 on the edge area 12 may be further reduced, thereby further improving the Si/EMC ratio of the edge area 12 of the redistribution layer 104, and thus further reducing the difference between the Si/EMC ratio of the edge area 12 and the Si/EMC ratio of the central area 11, which is conducive to better preventing warping of the redistribution layer 104.

In one embodiment, the edge dummy devices 301 mounted on a part of the upper surface of the edge area 12 close to the central area 11 are passive devices, and the edge dummy devices 301 mounted on a part of the upper surface far away from the central area 11 are heat dissipation discrete components or dummy chips, the mounting method of the passive devices (edge dummy devices 301) close to the central area 11 may be the same as the mounting method of the chip module 20 to maintain consistency in mounting methods and reduce the generation of stress.

Another embodiment of the present application further provides a method for forming a wafer scale system-in-package structure, and the formation method is described below in conjunction with the accompanying drawings (it should be noted that the same or similar parts of the present embodiment (method for forming a wafer scale system-in-package structure) and the aforementioned embodiment (wafer scale system-in-package structure) are not repeated in the present embodiment, for the details, reference may be made to the definitions or descriptions of the corresponding parts in the aforementioned embodiment).

Referring to FIGS. 1 and 2, the formation method includes: forming a redistribution layer 104, the redistribution layer including opposed upper surface and lower surface; providing a plurality of chip modules 20, mounting the plurality of chip modules 20 on the upper surface of the redistribution layer 104 and electrically connecting it with the redistribution layer 104; providing a back surface bridge chip 423, mounting the back surface bridge chip 423 on the lower surface of the redistribution layer 104 and electrically connecting it with the redistribution layer 104, and the back surface bridge chip 423 is used to interconnect adjacent chip modules 20; and covering the chip modules 20 by a first molding layer 111 on the upper surface of the redistribution layer 104, and the first molding layer 111 exposes the upper surface of the chip modules 20.

In one embodiment, the process of forming the redistribution layer 104 includes: providing a carrier board (not shown in the FIGS); forming a redistribution layer 104 on the carrier board, the redistribution layer 104 includes a passivation layer 100 and a plurality of discrete first wirings 102 and a plurality of discrete second wirings 103 located in the passivation layer 100; after forming the first molding layer 111, removing the carrier board and mounting the back surface bridge chip 423; the electrical connection of the plurality of chip modules 20 with the redistribution layer 104 includes: the chip modules 20 are electrically connected with a part of the first wirings 102 and a part of the second wirings 103.

In one embodiment, the back surface bridge chip 423 includes a substrate and connection lines located on the substrate; the electrical connection of the back surface bridge chip 423 with the redistribution layer 104 includes: the connection lines in the back surface bridge chip 423 are electrically connected with a part of the second wirings 103, and the back surface bridge chip 423 together with a part of the second wirings 103 interconnects adjacent chip modules 20.

In one embodiment, the chip module 20 includes: a base substrate 200, a plurality of semiconductor chips 201, and a covering molding layer 208, wherein the base substrate 200 includes opposed front surface and back surface, and the base substrate 200 has in it a connection structure 205, and the back surface of the base substrate 200 has external terminals 207, and the external terminals 207 are electrically connected with the connection structure 205 and electrically connected with a part of the first wirings 102 and a part of the second wirings 103, a plurality of semiconductor chips 201 are mounted on the front surface of the base substrate 200, and the semiconductor chips 201 are electrically connected with the connection structure 205, and the covering molding layer 208 is located on the front surface of the base substrate 200 and covers a plurality of the semiconductor chips 201.

In one embodiment, the type of the base substrate 200 is a silicon base substrate, a glass base substrate, or a redistribution base substrate.

In one embodiment, referring to FIG. 4, when the base substrate 200 is a redistribution base substrate, a second bridge chip 210 is further embedded in the redistribution base substrate, and the second bridge chip 210 is electrically connected with a part of the connection structure 205 in the redistribution base substrate.

In one embodiment, the corresponding base substrates 200 in at least two adjacent chip modules 20 in the system-in-package structure are of the same type or different types.

In one embodiment, the corresponding base substrates 200 in at least two adjacent chip modules 20 in the system-in-package structure are of the same type includes: the corresponding base substrates 200 in at least two adjacent chip modules 20 in the system-in-package structure are both silicon base substrates (referring to FIG. 2); or the corresponding base substrates 200 in at least two adjacent chip modules 20 in the system-in-package structure are both glass base substrates (referring to FIG. 2); or the corresponding base substrates 200 in at least two adjacent chip modules 20 in the system-in-package structure are both redistribution base substrates (without embedded bridge chips) (referring to FIG. 3); or the corresponding base substrates 200 in at least two adjacent chip modules 20 in the system-in-package structure are both redistribution base substrates embedded with a second bridge chip 210 (referring to FIG. 3).

In another embodiment, the corresponding base substrates 200 in at least two adjacent chip modules 20 in the system-in-package structure are of different types includes:
the types of the corresponding base substrates 200 in at least two adjacent chip modules 20 in the system-in-package structure are: one type is a silicon base substrate and another type is a glass base substrate; or the types of the corresponding base substrates 200 in at least two adjacent chip modules 20 in the system-in-package structure are: one type is a silicon base substrate and another type is a redistribution base substrate (referring to FIG. 5); or the types of the corresponding base substrates 200 in at least two adjacent chip modules 20 in the system-in-package structure are: one type is a glass base substrate and another type is a redistribution base substrate (referring to FIG. 5); or the types of the corresponding base substrates 200 in at least two adjacent chip modules 20 in the system-in-package structure are: one type is a redistribution base substrate (without embedded bridge chips) and another type is a redistribution base substrate embedded with a second bridge chip 210 (referring to FIG. 6); or the types of the corresponding base substrates 200 in at least two adjacent chip modules 200 in the system-in-package structure are: one type is a silicon substrate or a glass substrate, and another type is a redistribution base substrate embedded with a second bridge chip 210 (referring to FIG. 7).

In one embodiment, referring to FIGS. 8-10, it further includes: mounting a first bridge structure 421 on the top surface of the redistribution layer 104 at the edge of the chip module 20, and the first bridge structure 421 is used to interconnect adjacent chip modules 20.

In one embodiment, referring again to FIGS. 8-10, it further includes: mounting a second bridge structure 422 on the upper surface of the redistribution layer 104 at the corner head of the chip module 20, and the second bridge structure 422 is used to interconnect adjacent chip modules 20 around the corner head; and mounting edge dummy devices 301 of different sizes on the upper surface and/or lower surface of the edge area 12 of the redistribution layer 104 outside the array of chip modules 20.

Although the present application has been disclosed above with some embodiments, it is not intended to limit the present application. Any person skilled in the art may make possible changes and modifications to the technical solutions disclosed herein without departing from the spirit and scope of the present application, therefore, any simple modifications, equivalent changes, and refinements made to the above embodiments based on the technical essence of the present application that do not depart from the content of the technical solutions of the present application, shall fall within the scope of protection of the technical solutions of the present application.

What is claimed is:

1. A wafer scale system-in-package structure, comprising:
a redistribution layer comprising an upper surface and a lower surface opposite to the upper surface;
a plurality of chip modules mounted on the upper surface of the redistribution layer and electrically connected to the redistribution layer;
a back surface bridge chip mounted on the lower surface of the redistribution layer and electrically connected to the redistribution layer, wherein the back surface bridge chip is configured to interconnect adjacent chip modules; and
a first molding layer located on the upper surface of the redistribution layer, covering the chip modules, wherein the first molding layer exposes the upper surface of the chip modules.

2. The wafer scale system-in-package structure according to claim 1, wherein the redistribution layer comprises a passivation layer, a plurality of first wirings, and a plurality of second wirings located within the passivation layer; and
wherein the plurality of chip modules being electrically connected to the redistribution layer comprises: the plurality of chip modules being electrically connected to a part of the first wirings and a part of the second wirings.

3. The wafer scale system-in-package structure according to claim 2, wherein the back surface bridge chip comprises a substrate and connection lines located on the substrate; and wherein the back surface bridge chip being electrically connected to the redistribution layer comprises: the connection lines are electrically connected to the part of the second wirings, and the back surface bridge chip and the part of the second wirings is configured to interconnect the adjacent chip modules.

4. The wafer scale system-in-package structure according to claim 2, wherein each of the chip modules comprises:
a base substrate comprising a front surface, a back surface opposite to the front surface, and a connection structure, wherein the back surface of the base substrate has external terminals electrically connected to the connection structure and electrically connected to the part of the first wirings and the part of the second wirings;
a plurality of semiconductor chips mounted on the front surface of the base substrate and electrically connected to the connection structure; and
a covering molding layer on the front surface of the base substrate and covering the plurality of semiconductor chips.

5. The wafer scale system-in-package structure according to claim 4, wherein the base substrate comprises a silicon base substrate, a glass base substrate, or a redistribution base substrate.

6. The wafer scale system-in-package structure according to claim 5, wherein when the base substrate is a redistribution base substrate, a second bridge chip is further embedded in the redistribution base substrate and is electrically connected to a portion of the connection structure in the redistribution base substrate.

7. The wafer scale system-in-package structure according to claim 5, wherein the base substrates in at least two adjacent chip modules are the same or different.

8. The wafer scale system-in-package structure according to claim 7, wherein the base substrates in at least two adjacent chip modules are the same comprises:
both being silicon base substrates;
both being glass base substrates; or
both being redistribution base substrates; and
wherein the base substrates in at least two adjacent chip modules are different comprises:
one being a silicon base substrate and the other being a glass base substrate;
one being a silicon base substrate and the other being a redistribution base substrate; or
one being a glass base substrate and the other being a redistribution base substrate.

9. The wafer scale system-in-package structure according to claim 5, wherein the connection structure comprises one or more of: a metal layer; a connection plug; a through-via connection structure, or a via connection structure.

10. The wafer scale system-in-package structure according to claim 2, further comprising:
a plurality of metal bumps on the lower surface of the redistribution layer, wherein each of the plurality of metal bumps is electrically connected to a corresponding first wiring; and
a second molding layer on the lower surface of the redistribution layer, covering the metal bumps and the back surface bridge chip, wherein the second molding layer exposes a lower surface of the metal bumps.

11. The wafer scale system-in-package structure according to claim 2, further comprising:
a first bridge structure mounted on the upper surface of the redistribution layer at an edge of one of the chip modules, wherein the first bridge structure is configured to interconnect adjacent chip modules.

12. The wafer scale system-in-package structure according to claim 11, further comprising:
a second bridge structure mounted on the upper surface of the redistribution layer at a corner of one of the chip modules, wherein the second bridge structure is configured to interconnect adjacent chip modules around the corner; and
edge dummy devices of different sizes mounted on the upper surface or the lower surface of edge areas of the redistribution layer outside an array of the chip modules,
wherein the edge dummy devices comprise one or more of: a passive device, a heat dissipation device, or a dummy chip.

13. The wafer scale system-in-package structure according to claim 12, wherein:
the redistribution layer further comprises:
a plurality of third wirings in the passivation layer, and the chip modules are electrically connected to a part of the third wirings;
the first bridge structure comprises:
a first line layer; and
a first support layer on an upper surface of the first line layer, wherein the first line layer comprises:
a first dielectric layer;
first lines in the first dielectric layer; and
a first welding bump protruding from a lower surface of the first dielectric layer and electrically connected to the first lines; and
when the first bridge structure is mounted on the redistribution layer, the first welding bump is electrically connected to corresponding third wirings, such that the first bridge structure and the third wirings are configured to interconnect the adjacent chip modules.

14. The wafer scale system-in-package structure according to claim 12, wherein:
the redistribution layer further comprises:
a plurality of fourth wirings in the passivation layer;
the chip modules are electrically connected to a part of the fourth wirings;
the second bridge structure comprises:
a second line layer; and
a second support layer on an upper surface of the second line layer, wherein the second line layer comprises:
a second dielectric layer;
second lines in the second dielectric layer; and
a second welding bump protruding from the lower surface of the second dielectric layer and electrically connected to the second lines; and
when the second bridge structure is mounted on the redistribution layer, the second welding bump is electrically connected to the corresponding fourth wirings in the redistribution layer, and the second bridge structure and the fourth wirings are configured to interconnect the adjacent chip modules around the corner.

15. A method for forming a wafer scale system-in-package structure, comprising:
forming a redistribution layer comprising an upper surface and a lower surface opposite to the upper surface;
providing a plurality of chip modules and mounting the plurality of chip modules on the upper surface of the redistribution layer, wherein the plurality of chip modules are electrically connected to the redistribution layer;
providing a back surface bridge chip and mounting the back surface bridge chip on the lower surface of the redistribution layer, wherein the back surface bridge chip is electrically connected to the redistribution layer and is configured to interconnect adjacent chip modules of the plurality of chip modules; and
forming a first molding layer on the upper surface of the redistribution layer to cover the plurality of chip modules, wherein the first molding layer exposes an upper surface of each of the plurality of chip modules.

16. The method for forming a wafer scale system-in-package structure according to claim 15, wherein forming the redistribution layer comprises:
providing a carrier board;
forming the redistribution layer on the carrier board, wherein the redistribution layer comprises: a passivation layer; a plurality of first wirings; and a plurality of second wirings in the passivation layer;
after forming the first molding layer, removing the carrier board; and
mounting the back surface bridge chip on the lower surface of the redistribution layer, wherein the plurality of chip modules being electrically connected to the redistribution layer comprises: the plurality of chip modules being electrically connected to a part of the first wirings and a part of the second wirings.

17. The method for forming a wafer scale system-in-package structure according to claim 16, wherein:
the back surface bridge chip comprises:
a substrate; and
connection lines on the substrate; and
the back surface bridge chip is electrically connected to the redistribution layer comprises: the back surface bridge chip is electrically connected to the part of the second wirings, and the back surface bridge chip and the part of the second wirings are configured to interconnect adjacent chip modules.

18. The method for forming a wafer scale system-in-package structure according to claim 16, wherein each of the chip modules comprises:
a base substrate comprising: a front surface; a back surface opposite to the front surface; and a connection structure, wherein the back surface of the base substrate has a plurality of external terminals electrically connected to the connection structure;
a plurality of semiconductor chips mounted on the front surface of the base substrate and electrically connected to the connection structure; and
a covering molding layer on the front surface of the base substrate, covering the plurality of semiconductor chips,
wherein the external terminals on the back surface of the base substrate are electrically connected to the part of the first wirings and the part of the second wirings in the redistribution layer,
wherein the base substrate is a silicon base substrate, a glass base substrate, or a redistribution base substrate, and
wherein the base substrates in at least two adjacent chip modules are the same or different.

19. The method for forming a wafer scale system-in-package structure according to claim 18, wherein when the base substrate is a redistribution base substrate, a second bridge chip is further embedded in the redistribution base substrate and is electrically connected to a part of the connection structure in the redistribution base substrate.

20. The method for forming a wafer scale system-in-package structure according to claim 15, further comprising:
mounting a first bridge structure on the upper surface of the redistribution layer at an edge of one of the chip modules, and the first bridge structure is configured to interconnect adjacent chip modules;
mounting a second bridge structure on the upper surface of the redistribution layer at a corner of the one of the chip modules; and
mounting edge dummy devices of different sizes on the upper surface or the lower surface of the redistribution layer in edge areas located outside an array of the chip modules.
